(19) United States
(12) Patent Application Publication
(10) Pub. No.: US 2015/0368798 A1
(43) Pub. Date: Dec. 24, 2015

(54) Apparatus And Process Containment For Spatially Separated Atomic Layer Deposition

(71) Applicants: Garry K. KWONG, San Jose, CA (US); Joseph YUDOVSKY, Campbell, CA (US); Steven D. MARCUS, San Jose, CA (US)

(72) Inventor: Garry K. Kwong, San Jose, CA (US)

(21) Appl. No.: 14/766,670

(22) PCT Filed: Feb. 18, 2014
(86) PCT No.: PCT/US14/16924

§ 371 Date: Aug. 7, 2015

Related U.S. Application Data
(60) Provisional application No. 61/765,899, filed on Feb. 18, 2013.

(51) Int. Cl. C23C 16/455; C23C 16/458

(52) U.S. Cl. CPC C23C 16/45544; C23C 16/45563; C23C 16/45551; C23C 16/458

(57) ABSTRACT

Provided are atomic layer deposition apparatus and methods including a gas distribution plate comprising a plurality of elongate gas ports with gas curtains extending along the outer length of the gas distribution plate. Also provided are atomic layer deposition apparatuses and methods including a gas distribution plate with a plurality of elongate gas ports with gas curtains.

### BACKGROUND

Embodiments of the invention generally relate to an apparatus and a method for depositing materials. More specifically, embodiments of the invention are directed to a atomic layer deposition chambers which contain the process gases within a certain area and prevent process gases from leaking out of the process area and contaminate the process chamber.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are introduced into a process chamber containing a substrate. Generally, a first reactant is introduced into a process chamber and is adsorbed onto the substrate surface. A second reactant is introduced into the process chamber and reacts with the first reactant to form a deposited material. A purge step may be carried out to ensure that the only reactions that occur are on the substrate surface. The purge step may be a continuous purge with a carrier gas or a pulse purge between the delivery of the reactant gases.

In some spatial ALD gas distribution apparatus, the gases can leak out of the process area and contaminate the chamber. This, in turn, can create particles and corrosion problems. Embodiments, of the invention prevent the process gases from leaking out of the process area so that there is no more particles and corrosion problems.

There is an ongoing need in the art for improved apparatuses and methods for processing substrates by atomic layer deposition.

### SUMMARY

Embodiments of the invention are directed to gas distribution plates comprising a body having a length, width, left side, right side and front face. The body has a plurality of elongate gas ports with openings at the front face. The elongate gas ports extend along the width of the body. A left gas curtain channel extends along the length of the body adjacent the left side of the body and bounding at least some of the plurality of elongate gas ports. A right gas curtain channel extends along the length of the body adjacent the right side of the body and bounding at least some of the plurality of elongate gas ports.

In some embodiments, one or more of the left gas curtain channel and the right gas curtain channel bound all of the elongate gas ports. In one or more embodiments, one or more of the left gas curtain channel and the right gas curtain channel bound less than all of the elongate gas ports.

In some embodiments, one or more of the left gas curtain channel and the right gas curtain channel comprise a purge gas curtain channel. In one or more embodiments, one or more of the left gas curtain channel and the right gas curtain channel comprise a vacuum curtain channel. In some embodiments, one or more of the left gas curtain channel and the right gas curtain channel comprise a purge gas curtain channel and a vacuum curtain channel. In one or more embodiments, the purge gas curtain channel is between the vacuum curtain channel and the plurality of elongate gas ports. In some embodiments, the vacuum curtain channel is between the purge gas curtain channel and the plurality of elongate gas ports.

In some embodiments, the plurality of elongate gas ports comprise at least one first reactive gas port in fluid communication with a first reactive gas and at least one second reactive gas port in fluid communication with a second reactive gas different from the first reactive gas. In one or more embodiments, the plurality of elongate gas ports consist essentially of, in order, a leading first reactive gas port, a second reactive gas port and a trailing first reactive gas port. In some embodiments, the plurality of elongate gas ports further comprises a purge gas port between the leading first reactive gas port and the second reactive gas port, and a purge gas port between the second reactive gas port and the trailing first reactive gas port, each purge gas port separated from the reactive gas ports by a vacuum port. In one or more embodiments, the elongate gas ports comprise, in order, a vacuum port, a purge gas port and another vacuum port before the leading first reactive gas port and after the second first reactive gas port.

In some embodiments, the plurality of elongate gas ports comprise at least one repeating unit of a first reactive gas port and a second reactive gas port. In one or more embodiments, there are in the range of 2 to 24 repeating units.

Additional embodiments of the invention are directed to atomic layer deposition systems. The ALD systems comprise a processing chamber, a gas distribution plate according to any of the disclosed embodiments and a substrate carrier. The substrate carrier able to move a substrate reciprocally with respect to the gas distribution plate in a back and forth motion along an axis perpendicular to an axis of the elongate gas injectors.

In some embodiments, the substrate carrier rotates the substrate. In one or more embodiments, the rotation is continuous. In some embodiments, the rotation is in discrete steps. In some embodiments, each discrete step rotation occurs when the substrate carrier is not adjacent the gas distribution plate.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic side view of an atomic layer deposition chamber according to one or more embodiments of the invention;

FIG. 2 shows a susceptor in accordance with one or more embodiments of the invention;

FIG. 3 show a partial perspective view of an atomic layer deposition chamber in accordance with one or more embodiments of the invention;

FIGS. 4A and 4B show a views of a gas distribution plate in accordance with one or more embodiments of the invention;

FIG. 5 shows a schematic cross-sectional view of a gas distribution plate in accordance with one or more embodiments of the invention;

FIG. 6 shows a schematic cross-sectional view of a gas distribution plate in accordance with one or more embodiments of the invention;

FIG. 7 shows a schematic view of the front face of a gas distribution plate in accordance with one or more embodiments of the invention;

FIG. 8 shows a schematic cross-sectional view of a gas distribution plate in accordance with one or more embodiments of the invention;

FIG. 9 shows a schematic view of the front face of a gas distribution plate in accordance with one or more embodiments of the invention;

FIG. 10 shows a schematic cross-sectional view of a gas distribution plate in accordance with one or more embodiments of the invention;

FIG. 11 shows a schematic view of the front face of a gas distribution plate in accordance with one or more embodiments of the invention;

FIG. 12 shows a schematic view of the front face of a gas distribution plate in accordance with one or more embodiments of the invention;

FIG. 13 shows a schematic view of the front face of a gas distribution plate in accordance with one or more embodiments of the invention; and

FIG. 14 shows a cluster tool in accordance with one or more embodiment of the invention.

### DETAILED DESCRIPTION

Embodiments of the invention are directed to atomic layer deposition apparatus and methods which provide improved movement of substrates. Specific embodiments of the invention are directed to atomic layer deposition apparatuses (also called cyclical deposition) incorporating a gas distribution plate having a detailed configuration and reciprocal linear motion.

Embodiments of the invention are generally related to spatial atomic layer deposition apparatus. In particular, embodiments of the invention describe how to contain the process within a certain area and prevent process gases from leaking out of the process area and contaminate the process chamber. In some spatial ALD type gas distribution apparatus, the gases can leak out of the process area and contaminate the chamber. This, in turn, can create particles and corrosion problems. Embodiments, of the invention prevent the process gases from leaking out of the process area so that there is no more particles and corrosion problems.

One or more embodiments of the invention add an additional inert gas purge channel and/or exhaust channel at all edges of a spatial ALD apparatus. In some embodiments, the pressure at these exhaust channels to prevent the process gases from leaking out of the apparatus area. Embodiments of the invention help contain the process gases, any by-products and/or debris within the apparatus (process area), which can keep the whole process chamber clean, eliminate particle and corrosion problems, increase the life of the parts, thereby reducing costs, and shorten the periodic maintenance duration.

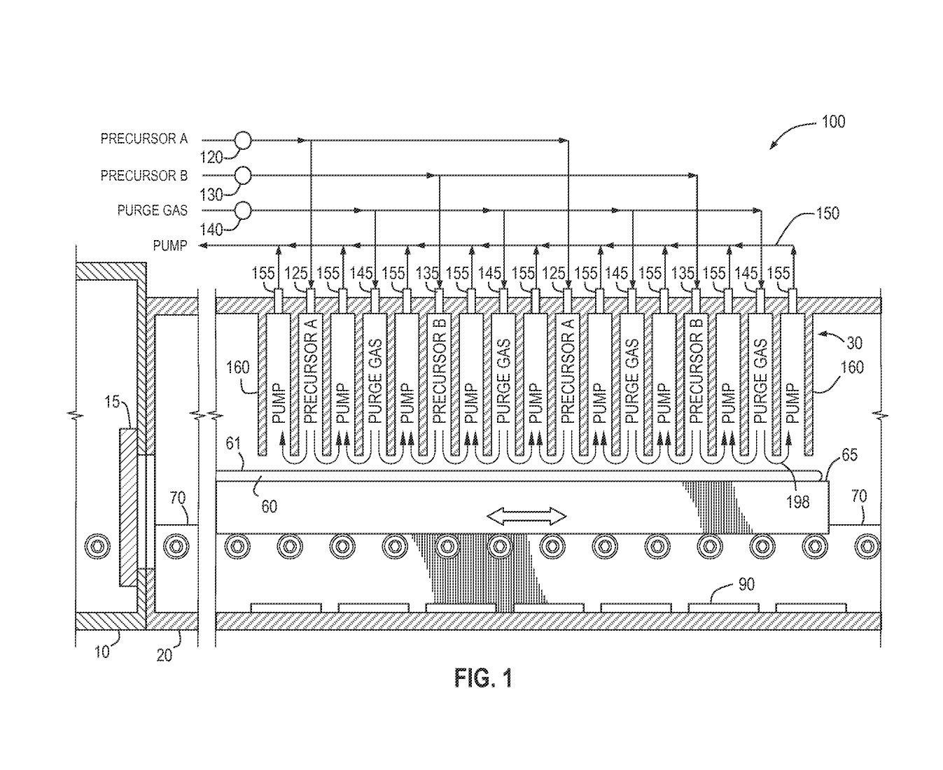

FIG. 1 is a schematic cross-sectional view of an atomic layer deposition system 100 or reactor in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

The gas distribution plate 30 comprises a plurality of gas ports configured to transmit one or more gas streams to the substrate 60 and a plurality of vacuum ports disposed between each gas port and configured to transmit the gas streams out of the processing chamber 20. In the detailed embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example about 0.5 mm from the first surface 61, This distance should be such that the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution systems may be employed.

In operation, a substrate 60 is delivered (e.g., by a robot) to the load lock chamber 10 and is placed on a carrier 65. After the isolation valve 15 is opened, the carrier 65 is moved along the track 70, which may be a rail or frame system. Once the carrier 65 enters in the processing chamber 20, the isolation valve 15 closes, sealing the processing chamber 20. The carrier 65 is then moved through the processing chamber 20 for processing. In one embodiment, the carrier 65 is moved in a linear path through the chamber.

As the substrate 60 moves through the processing chamber 20, the first surface 61 of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the first surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps.

Sufficient space is generally provided at the end of the processing chamber 20 so as to ensure complete exposure by the last gas port in the processing chamber 20. Once the substrate 60 reaches the end of the processing chamber 20 (i.e., the first surface 61 has completely been exposed to every gas port in the chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 110. The width between each partition, the number of gas ports disposed on the processing chamber 20, and the number of times the substrate is passed back and forth may also determine the extent to which the substrate surface 110 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 110 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward.

In yet another embodiment, the system 100 may be configured to process a plurality of substrates. In such an embodiment, the system 100 may include a second load lock chamber (disposed at an opposite end of the load lock chamber 10) and a plurality of substrates 60. The substrates 60 may be delivered to the load lock chamber 10 and retrieved from the second load lock chamber.

In one or more embodiments, at least one radiant heat lamps 90 is positioned to heat the second side of the substrate. The radiant heat source is generally positioned on the opposite side of gas distribution plate 30 from the substrate. In these embodiments, the gas cushion plate is made from a material which allows transmission of at least some of the light from the radiant heat source. For example, the gas cushion plate can be made from quartz, allowing radiant energy from a visible light source to pass through the plate and contact the back side of the substrate and cause an increase in the temperature of the substrate.

In some embodiments, the carrier 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

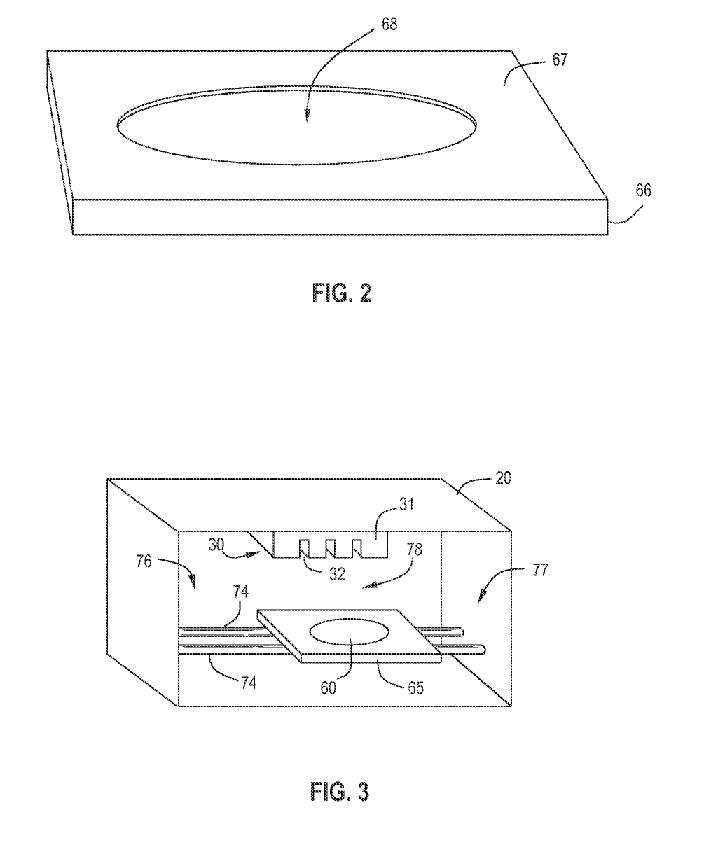

In still another embodiment, the top surface 67 of the susceptor 66 includes a recess 68 configured to accept the substrate 60, as shown in FIG. 2. The susceptor 66 is generally thicker than the thickness of the substrate so that there is susceptor material beneath the substrate. In detailed embodiments, the recess 68 is configured such that when the substrate 60 is disposed inside the recess 68, the first surface 61 of substrate 60 is level with the top surface 67 of the susceptor 66. Stated differently, the recess 68 of some embodiments is configured such that when a substrate 60 is disposed therein, the first surface 61 of the substrate 60 does not protrude above the top surface 67 of the susceptor 66.

FIG. 3 shows a partial cross-sectional view of a processing chamber 20 in accordance with one or more embodiments of the invention. The processing chamber 20 has a gas distribution plate 30 with at least one gas injector unit 31. As used in this specification and the appended claims, the term “gas injector unit” is used to describe a sequence of gas outlets in a gas distribution plate 30 which are capable of depositing a discrete film on a substrate surface. For example, if a discrete film is deposited by combination of two components, then a single gas injector unit would include outlets for at least those two components. A gas injector unit 31 can also include any purge gas ports or vacuum ports within and around the gas outlets capable of depositing a discrete film. The gas distribution plate 30 shown in FIG. 1 is made up of a single gas injector unit 31, but it should be understood that more than one gas injector unit 31 could be part of the gas distribution plate 30.

In some embodiments, the processing chamber 20 includes a substrate carrier 65 which is configured to move a substrate along a linear reciprocal path along an axis perpendicular to the elongate gas injectors. As used in this specification and the appended claims, the term “linear reciprocal path” refers to either a straight or slightly curved path in which the substrate can be moved back and forth. Stated differently, the substrate carrier may be configured to move a substrate reciprocally with respect to the gas injector unit in a back and forth motion perpendicular to the axis of the elongate gas injectors. As shown in FIG. 3, the carrier 65 may be supported on rails 74 which are capable of moving the carrier 65 reciprocally from left-to-right and right-to-left, or capable of supporting the carrier 65 during movement. Movement can be accomplished by many mechanisms known to those skilled in the art. For example, a stepper motor may drive one of the rails, which in turn can interact with the carrier 65, to result in reciprocal motion of the substrate 60. In detailed embodiments, the substrate carrier is configured to move a substrate 60 along a linear reciprocal path along an axis perpendicular to and beneath the elongate gas injectors 32. In specific embodiments, the substrate carrier 65 is configured to transport the substrate 60 from a region 76 in front of the gas distribution plate 30 to a region 77 after the gas distribution plate 30 so that the entire substrate 60 surface passes through a region 78 occupied by the gas distribution plate 30.

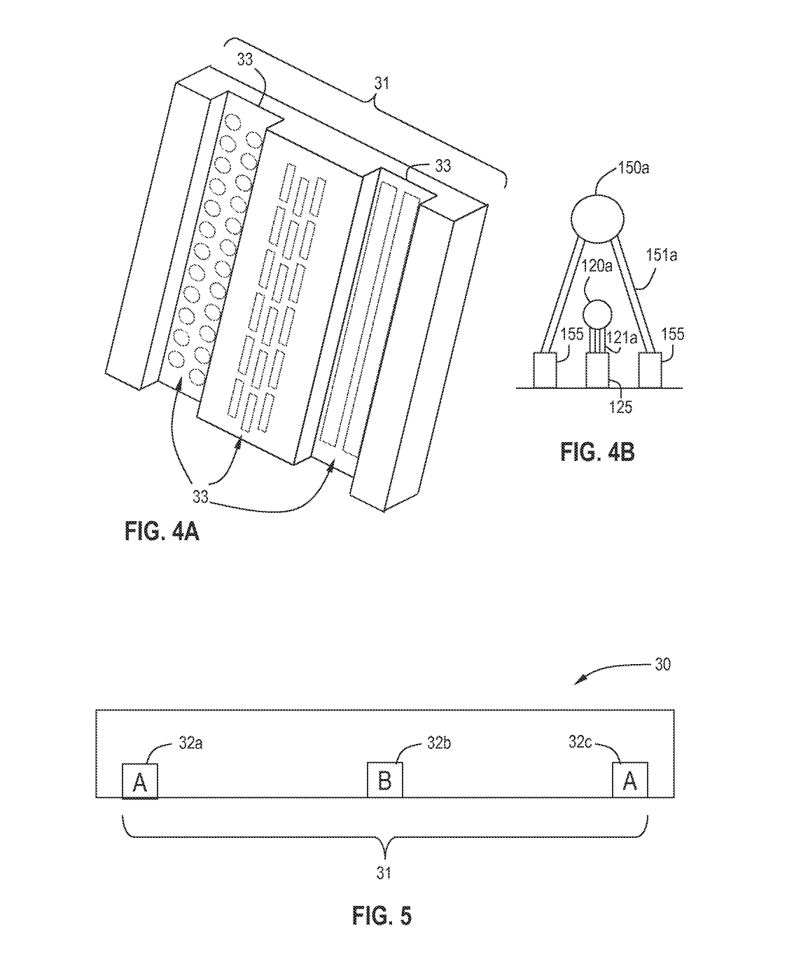

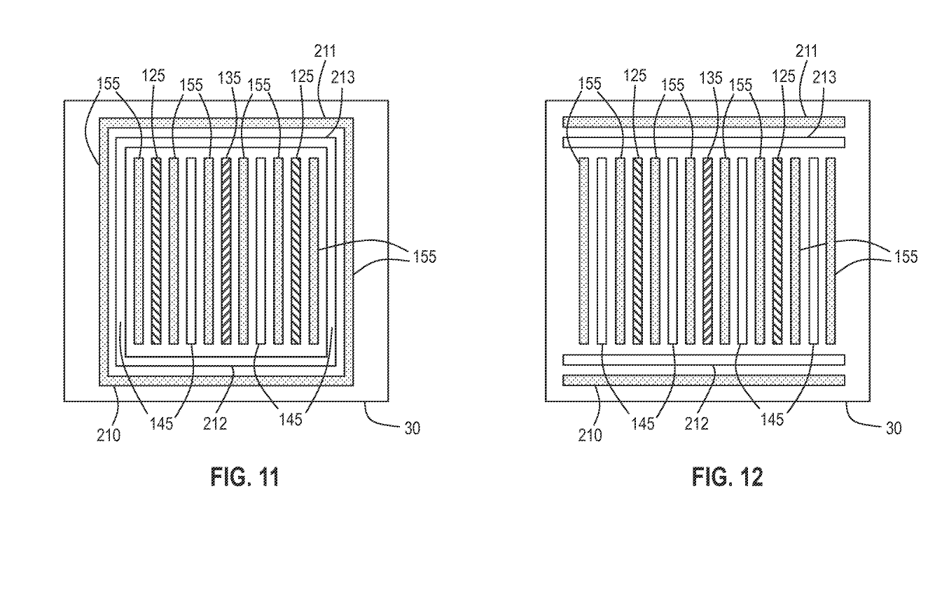

FIG. 4A shows a bottom perspective view of a gas distribution plate 30 in accordance with one or more embodiments of the invention. With reference to both FIGS. 3 and 4, each gas injector unit 31 comprises a plurality of elongate gas injectors 32. The elongate gas injectors 32 can be in any suitable shape or configuration with examples shown in FIG. 4A. The elongate gas injector 32 on the left of the drawing is a series of closely spaced holes. These holes are located at the bottom of a trench 33 formed in the face of the gas distribution plate 30. The trench 33 is shown extending to the ends of the gas distribution plate 30, but it will be understood that this is merely for illustration purposes and the trench does not need to extend to the edge. The elongate gas injector 32 in the middle is a series of closely spaced rectangular openings. This injector is shown directly on the face of the gas distribution plate 30 as opposed to being located within a trench 33. The trench of detailed embodiments has about 8 mm deep and has a width of about 10 mm. The elongate gas injector 32 on the right of FIG. 4A is shown as two elongate channels. FIG. 4B shows a side view of a portion of the gas distribution plate 30. A larger portion and description is included in FIG. 11. FIG. 4B shows the relationship of a single pumping plenum 150a with the vacuum ports 155. The pumping plenum 150a is connected to these vacuum ports 155 through two channels 151a. These channels 151 are in flow communication with the vacuum ports 155 by the elongate injectors 32 shown in FIG. 4A. In specific embodiments, the elongate injectors 32 have about 28 holes having a diameter of about 4.5 mm. In various embodiments, the elongate injectors 32 have in the range of about 10 to about 100 holes, or in the range of about 15 to about 75 holes, or in the range of about 20 to about 50 holes, or greater than 10 holes, 20 holes, 30 holes, 40 holes, 50 holes, 60 holes, 70 holes, 80 holes, 90 holes or 100 holes. In an assortment of embodiments, the holes have a diameter in the range of about 1 mm to about 10 mm, or in the range of about 2 mm to about 9 mm, or in the range of about 3 mm to about 8 mm, or in the range of about 4 mm to about 7 mm, or in the range of about 5 mm to about 6 mm, or greater than 1 mm, 2 mm, 3 mm, 4 mm, 5 mm, 6 mm, 7 mm, 8 mm, 9 mm or 10 mm. The holes can be lined up in two or more rows, scattered or evenly distributed, or in a single row. The gas supply plenum 120a is connected to the elongate gas injector 32 by two channels 121a. In detailed embodiments, the gas supply plenum 120a has a diameter of about 14 mm. In various embodiments, the gas supply plenum has a diameter in the range of about 8 mm to about 20 mm, or in the range of about 9 mm to about 19 mm, or in the range of about 10 mm to about 18 mm, or in the range of about 11 mm to about 17 mm, or in the range of about 12 mm to about 16 mm, or in the range of about 13 mm to about 15 mm, or greater than 4 mm, 5 mm, 6 mm, 7 mm, 8 mm, 9 mm, 10 mm, 11 mm, 12 mm, 13 mm, 14 mm, 15 mm, 16 mm, 17 mm, 18 mm, 19 mm or 20 mm. In specific embodiments, these channels (from the plenums) have a diameter about 0.5 mm and there are about 121 of these channels in two rows, either staggered or evenly spaced. In various embodiments, the diameter is in the range of about 0.1 mm to about 1 mm, or in the range of about 0.2 mm to about 0.9 mm, or in the range of about 0.3 mm to about 0.8 mm or in the range of about 0.4 mm to about 0.7 mm, or greater than 0.2 mm, 0.3 mm, 0.4 mm, 0.5 mm, 0.6 mm, 0.7 mm, 0.8 mm, 0.9 mm or 1 mm. Although the gas supply plenum 120a is associated numerically with the first precursor gas, it will be understood that similar configurations may be made for the second reactive gases and the purge gases. Without being bound by any particular theory of operation, it is believed that the dimensions of the plenums, channels and holes define the conductance of the channels and uniformity.

FIGS. 5-13 show side, partial cross-sectional views of gas distribution plates 30 in accordance with various embodiments of the invention. The letters used in these drawings represent some of the different gases which may be used in the system. As a reference, A is a first reactive gas, B is a second reactive gas, C is a third reactive gas, P is a purge gas and V is vacuum. As used in this specification and the appended claims, the term “reactive gas” refers to any gas which may react with either the substrate, a film or partial film on the substrate surface. Non-limiting examples of reactive gases include hafnium precursors, water, cerium precursors, peroxide, titanium precursors, ozone, plasmas, Groups III-V elements. Purge gases are any gas which is non-reactive with the species or surface it comes into contact with. Non-limiting examples of purge gases include argon, nitrogen and helium.

In the embodiments shown, the reactive gas injectors on either end of the gas distribution plate 30 are the same so that the first and last reactive gas seen by a substrate passing the gas distribution plate 30 is the same. For example, if the first reactive gas is A, then the last reactive gas will also be A. If gas A and B are switched, then the first and last gas seen by the substrate will be gas B. This is merely one possible example of the configuration and order of gas distribution. Those skilled in the art will understand that there are alternate configurations available and the scope of the invention should not be limited to such configurations.

Referring to FIG. 5, the gas injector unit 31 of some embodiments comprises a plurality of elongate gas injectors including at least two first reactive gas injectors A and at least one second reactive gas injector B which is a different gas than that of the first reactive gas injectors. The first reactive gas injectors A are in fluid communication with a first reactive gas, and the second reactive gas injectors B are in fluid communication with a second reactive gas which is different from the first reactive gas. The at least two first reactive gas injectors A surround the at least one second reactive gas injector B so that a substrate moving from left-to-right will see, in order, the leading first reactive gas A, the second reactive gas B and the trailing first reactive gas A, resulting in a full layer being formed on the substrate. A substrate returning along the same path will see the opposite order of reactive gases, resulting in two layers for each full cycle. As a useful abbreviation, this configuration may be referred to at an ABA injector configuration. A substrate moved back and forth across this gas injector unit 31 would see a pulse sequence of

AB AAB AAB (AAB)ₙ . . . AABA

forming a uniform film composition of B. Exposure to the first reactive gas A at the end of the sequence is not important as there is no follow-up by a second reactive gas B. It will be understood by those skilled in the art that while the film composition is referred to as B, it is really a product of the surface reaction products of reactive gas A and reactive gas B and that use of just B is for convenience in describing the films.

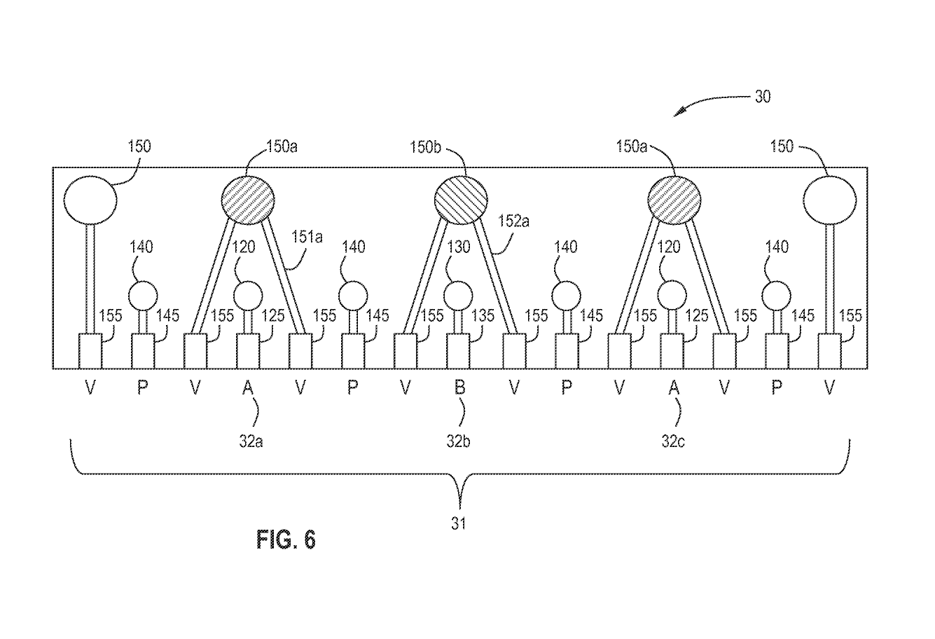

FIG. 6 shows a detailed embodiment of the gas distribution plate 30. As shown here, the gas distribution plate 30 comprises a single gas injector unit 31 which may include the outside purge gas P injectors and outside vacuum V ports. In the detailed embodiment shown, the gas distribution plate 30 comprises at least two pumping plenums connected to the pumping system 150. The first pumping plenum 150a is in flow communication with the vacuum ports 155 adjacent to (on either side of) the gas ports 125 associated with the first reactive gas A injectors 32a, 32c. The first pumping plenum 150a is connected to the vacuum ports 155 through two vacuum channels 151a. The second pumping plenum 150b is in flow communication with the vacuum ports 155 adjacent to (on either side of) the gas port 135 associated with the second reactive gas B injector 32b. The second pumping plenum 150b is connected to the vacuum ports 155 through two vacuum channels 152a. In this manner, the first reactive gas A and the second reactive gas B are substantially prevented from reacting in the gas phase. The vacuum channels in flow communication with the end vacuum ports 155 can be either the first vacuum channel 150a or the second vacuum channel 150b, or a third vacuum channel. The pumping plenums 150, 150a, 150b can have any suitable dimensions. The vacuum channels 151a, 152a can be any suitable dimension. In specific embodiments, the vacuum channels 151a, 152a have a diameter of about 22 mm. The end vacuum plenums 150 collect substantially only purge gases. An additional vacuum line collects gases from within the chamber. These four exhausts (A, B, purge gas and chamber) can be exhausted separately or combined downstream to one or more pumps, or in any combination with two separate pumps.

A specific embodiment of the invention is directed to an atomic layer deposition system comprising a processing chamber with a gas distribution plate therein. The gas distribution plate comprises a plurality of gas injectors consisting essentially of, in order, a vacuum port, a purge gas injector, a vacuum port, a first reactive gas injector, a vacuum port, a purge port, a vacuum port, a second reactive gas injector, a vacuum port, a purge port, a vacuum port, a first reactive gas injector, a vacuum port, a purge port and a vacuum port.

In some embodiments, the gas plenums and gas injectors may be connected with a purge gas supply (e.g., nitrogen). This allows the plenums and gas injectors to be purged of residual gases so that the gas configuration can be switched, allowing the B gas to flow from the A plenum and injectors, and vice versa. Additionally, the gas distribution plate 30 may include additional vacuum ports along sides or edges to help control unwanted gas leakage. As the pressure under the injector is about 1 torr greater than the chamber, the additional vacuum ports may help prevent reactive gases leaking into the chamber. In some embodiments, the gas distribution plate 30 also includes one or more heater or cooler.

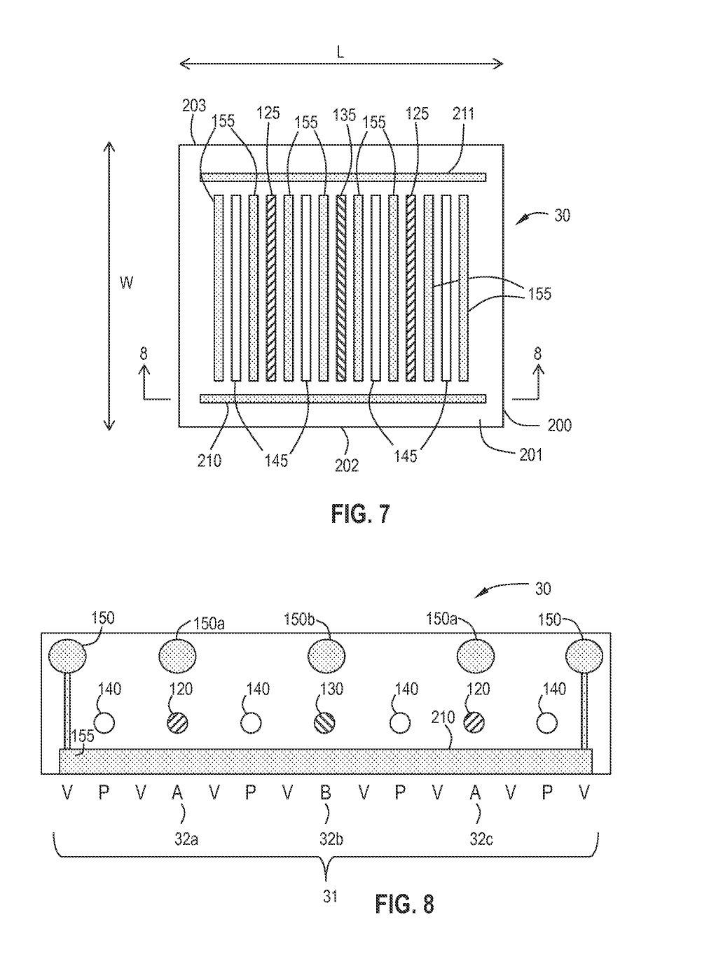

Referring to FIG. 7, a gas distribution plate 30 in accordance with one or more embodiment is shown. The gas distribution plate 30 includes a body 200 with a front face 201, length L and width W. The body 200 has a left side 202 (shown on the bottom) and a right side 203 (shown on the top). The left and right sides are determined based on a substrate moving from left to right with the left-most gas injector being the first gas injector seen by the substrate. The gas distribution plate 30 includes a plurality of elongate gas ports 125, 135, 145 with openings at the front face 201. The openings extend along the width W of the body 200 and front face 201.

Gas curtains channels are positioned along the left side 202 and right side 203 of the gas distribution plate 30 to prevent gases from the elongate injectors from migrating from the region in front of the front face 201. The embodiment shown in FIG. 7 includes a left gas curtain channel 210 and a right gas curtain channel 211. Both the left gas curtain channel 210 and right gas curtain channel 211 extend along the length L of the body 200 adjacent the left side and right side, respectively, of the body 200.

The gas curtain channels 210, 211 bound at least some of the plurality of elongate gas ports 125, 135, 145. As used in this specification and the appended claims, the term “bound”, and the like, used in this respect, means that the gas curtain channel forms a boundary between the edge of the elongate gas ports and the edge of the gas distribution plate. The length of the gas curtain channels 210, 211 can be adjusted for various uses. The gas curtain channels can be long enough to bound at least one of the elongate gas ports through all of the elongate gas inje ports ctors. FIG. 8 shows a cross-sectional side view of the gas distribution plate 30 shown in FIG. 7. The individual gas injectors 120, 130, 140 which pass through the body 200 are seen in cross-section, with the left gas curtain channel 210 extending the length L of the gas distribution plate 30. In the embodiment shown in FIG. 7, both the left gas curtain channel 210 and the right gas curtain channel 211 bound all of the elongate gas ports 125, 135, 145 including vacuum ports 155 on either side of the elongate gas ports 125, 135, 145. In some embodiments, the gas curtain channels bound less than all of the elongate gas ports. Both the left gas curtain channel 210 and the right gas curtain channel 211 are shown as vacuum curtain channels which provide a region of lower pressure. The pressure of the vacuum curtain channels can be the same as, or different than, the pressure in the vacuum ports 155. If the pressure of the vacuum curtain channels is too low, the reactive gases from the elongate gas ports may be preferentially drawn toward the curtain. If the pressure of the vacuum curtain channel is too high, the reactive gases may be able to escape the reaction area in front of the front face 201 of the gas distribution plate 30.

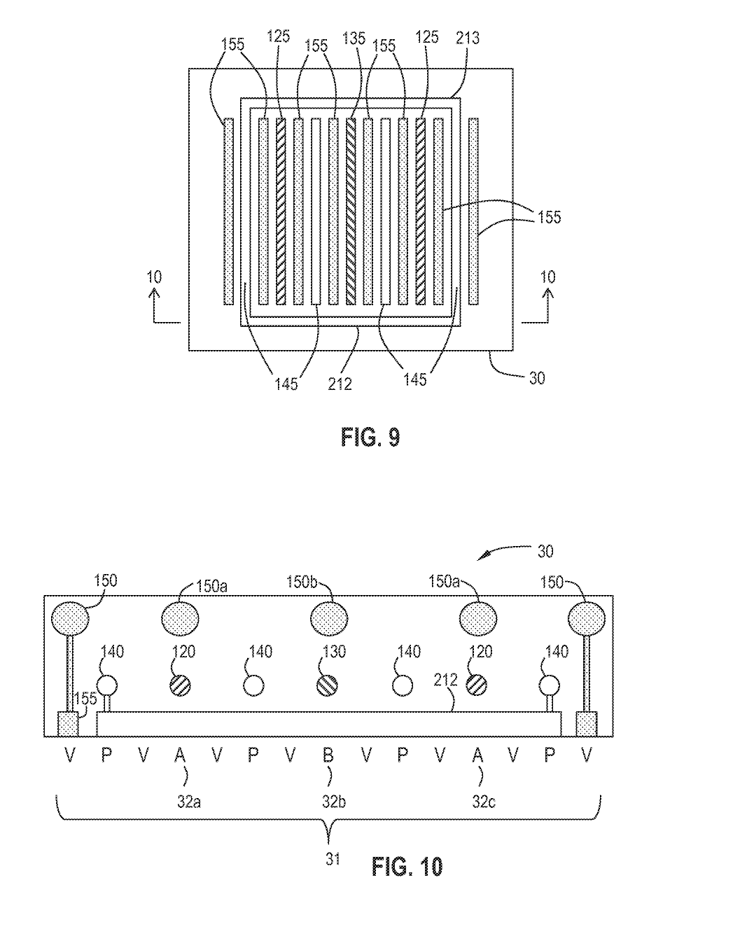

The gas curtain channels can be vacuum channels and/or purge gas channels. The embodiment shown in FIGS. 7 and 8 have a vacuum gas curtain channel bounding the elongate gas ports on both sides, left and right, of the gas distribution plate 30. The embodiment shown in FIGS. 9 and 10 have a purge gas curtain channel 211, 213 bounding the left and right sides, respectively, of the gas distribution plate 30.

The embodiment shown in FIG. 7 has a separate vacuum curtain channel 210, 211 than the end vacuum ports 155. However, these can be a single continuous vacuum port which acts as both the end vacuum port 155 and the vacuum curtain channels 210, 211. The embodiment shown in FIG. 9 includes a single purge gas curtain channel which extends around all of the elongate gas ports with the end vacuum ports 155 outside the curtain. Here, the purge gas curtain channel and purge gas ports are integrated into a single unit but have different functions depending on which portion of the unit is in question. Looking at FIG. 9, the left and right sides of the purge gas curtain would act as purge gas ports 145 while the bottom side would be the left purge gas curtain channel 212 and the top would act as the right purge gas curtain channel 213. In this case, the pressure in the channel would be about equal around the entire gas distribution plate 30. In an embodiment where the purge gas ports 145 and the purge gas curtain channels 212, 213 are separate, the gas pressure in these ports can be different. When the purge gas ports 145 and purge gas curtain channels 212, 213 are separate, the pressure can be separately controlled to ensure that the reactive gases remain within the process region in front of the front face 201 of the gas distribution plate 30. If the purge gas pressure in the purge gas curtain channels 212, 213 is too low, the purge gas curtain channels 212, 213 may not be effective to contain all of the reactive gases in the process region. However, if the purge gas pressure in the purge gas curtain channels 212, 213 is too high, the purge gas exiting the curtain channels may impact the reactive gases from the elongate gas ports, affecting the overall deposition quality.

FIG. 11 shows an embodiment of the invention in which there are two curtain channels. The inner curtain channel is a purge gas curtain channel and the outer curtain channel is a vacuum curtain channel. Both of these channels are shown as integrated with the end-most elongate gas ports. FIG. 12 shows an embodiment in which the curtain channels are separate from the elongate gas ports allowing independent control of the pressures in these curtain channels and gas ports.

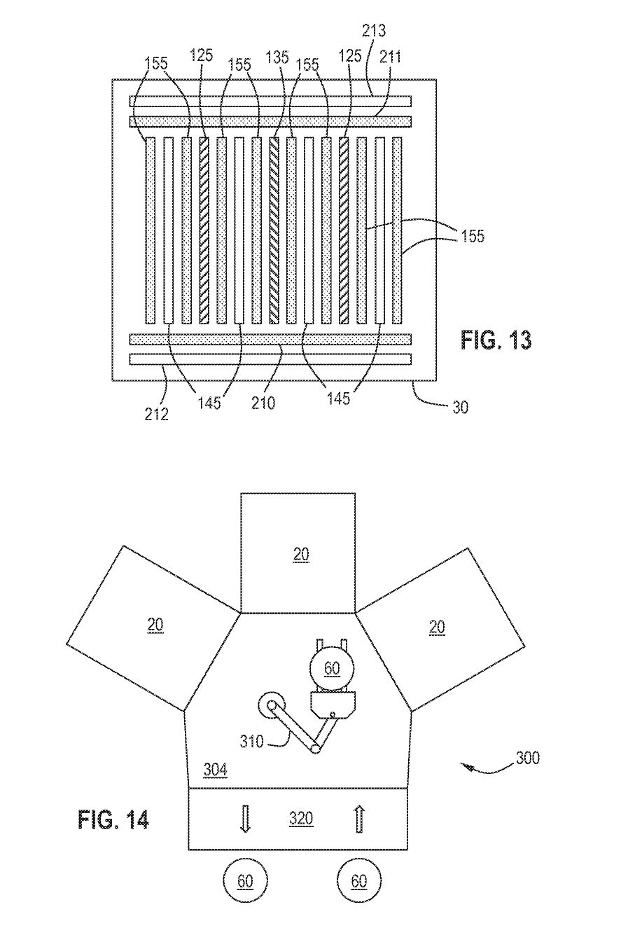

One or more of the left gas curtain channel and the right gas curtain channel comprise a purge gas curtain channel and a vacuum curtain channel. In the case shown in FIG. 12, both the left gas curtain channel and right gas curtain channel comprise both a vacuum curtain channel 210, 211 and a purge gas curtain channel 212, 213. The purge gas curtain channels 212, 213 are between the vacuum curtain channels 210, 211 and the plurality of elongate gas channels 125, 135, 145. FIG. 13 shows an embodiment in which the vacuum curtain channels 210, 211 are between the purge gas curtain channels 212, 213 and the plurality of elongate gas channels 125, 135, 145. In certain embodiments, rotational movement may also be employed after every stroke, or after multiple strokes. The rotational movement may be discrete movements, for example 10, 20, 30, 40, or 50 degree movements or other suitable incremental rotational movement. Such rotational movement together with linear movement may provide more uniform film formation on the substrate.

In detailed embodiments, the substrate carrier is configured to carry the substrate outside of the first extent 97 to a loading position. In some embodiments, the substrate carrier is configured to carry the substrate outside of the second extent 98 to an unloading position. The loading and unloading positions can be reversed if necessary.

Additional embodiments of the invention are directed to methods of processing a substrate. A portion of a substrate is passed across a gas injector unit in a first direction. As used in this specification and the appended claims, the term “passed across” means that the substrate has been moved over, under, etc., the gas distribution plate so that gases from the gas distribution plate can react with the substrate or layer on the substrate. In moving the substrate in the first direction, the substrate is exposed to, in order, a leading first reactive gas stream, a second reactive gas stream and a trailing first reactive gas stream to deposit a first layer. The portion of the substrate is then passed across the gas injector unit in a direction opposite of the first direction so that the portion of the substrate is exposed to, in order, the trailing first reactive gas stream, the second reactive gas stream and the leading first reactive gas stream to create a second layer. If there is only one gas injector unit, the substrate will be passed beneath the entire relevant portion of the gas distribution plate. Regions of the gas distribution plate outside of the reactive gas injectors is not part of the relevant portion. In embodiments where there is more than one gas injector unit, the substrate will move a portion of the length of the substrate based on the number of gas injector units. Therefore, for every n gas injector units, the substrate will move 1/nth of the total length of the substrate.

In detailed embodiments, the method further comprises exposing the portion of the substrate to a purge gas stream between each of the first reactive gas streams and the second reactive gas streams. The gases of some embodiments are flowing continuously. In some embodiments, the gases are pulsed as the substrate moves beneath the gas distribution plate.

According to one or more embodiments, passing the portion of the substrate in a first direction exposes the portion of the substrate to, in order, a leading first reactive gas stream, a leading second reactive gas stream, a first intermediate first reactive gas stream, a third reactive gas stream, a second intermediate first reactive gas stream, a trailing second reactive gas stream and a trailing first reactive gas stream, and passing the portion of the substrate in the second direction exposes the portion of the substrate to the gas streams in reverse order.

Additional embodiments of the invention are directed to cluster tools comprising at least one atomic layer deposition system described. The cluster tool has a central portion with one or more branches extending therefrom. The branches being deposition, or processing, apparatuses. Cluster tools which incorporate the short stroke motion require substantially less space than tools with conventional deposition chambers. The central portion of the cluster tool may include at least one robot arm capable of moving substrates from a load lock chamber into the processing chamber and back to the load lock chamber after processing. Referring to FIG. 14, an illustrative cluster tool 300 includes a central transfer chamber 304 generally including a multi-substrate robot 310 adapted to transfer a plurality of substrates in and out of the load lock chamber 320 and the various process chambers 20. Although the cluster tool 300 is shown with three processing chambers 20, it will be understood by those skilled in the art that there can be more or less than 3 processing chambers. Additionally, the processing chambers can be for different types (e.g., ALD, CVD, PVD) of substrate processing techniques.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. A gas distribution plate comprising
a body having a length, width, left side, right side and front face;
a plurality of elongate gas ports with openings at the front face of the body, the elongate gas ports extending along the width of the body,
a left gas curtain channel extending along the length of the body adjacent the left side of the body and bounding at least some of the plurality of elongate gas ports; and
a right gas curtain channel extending along the length of the body adjacent the right side of the body and bounding at least some of the plurality of elongate gas ports.

2. The gas distribution plate of claim 1, wherein one or more of the left gas curtain channel and the right gas curtain channel bound all of the elongate gas ports.

3. The gas distribution plate of claim 1, wherein one or more of the left gas curtain channel and the right gas curtain channel bound less than all of the elongate gas ports.

4. The gas distribution plate of claim 1, wherein one or more of the left gas curtain channel and the right gas curtain channel comprise a purge gas curtain channel.

5. The gas distribution plate of claim 1, wherein one or more of the left gas curtain channel and the right gas curtain channel comprise a vacuum curtain channel.

6. The gas distribution plate of claim 1, wherein one or more of the left gas curtain channel and the right gas curtain channel comprise a purge gas curtain channel and a vacuum curtain channel.

7. The gas distribution plate of claim 6, wherein the purge gas curtain channel is between the vacuum curtain channel and the plurality of elongate gas ports.

8. The gas distribution plate of claim 6, wherein the vacuum curtain channel is between the purge gas curtain channel and the plurality of elongate gas ports.

9. The gas distribution plate of claim 1, wherein the plurality of elongate gas ports comprise at least one first reactive gas port in fluid communication with a first reactive gas and at least one second reactive gas port in fluid communication with a second reactive gas different from the first reactive gas.

10. The gas distribution plate of claim 9, wherein the plurality of elongate gas ports consist essentially of, in order, a leading first reactive gas port, a second reactive gas port and a trailing first reactive gas port.

11. The gas distribution plate of claim 10, wherein the plurality of elongate gas ports further comprises a purge gas port between the leading first reactive gas port and the second reactive gas port, and a purge gas port between the second reactive gas port and the trailing first reactive gas port, each purge gas port separated from the reactive gas ports by a vacuum port.

12. The gas distribution plate of claim 11, wherein the elongate gas ports comprise, in order, a vacuum port, a purge gas port and another vacuum port before the leading first reactive gas port and after the second first reactive gas port.

13. The gas distribution plate of claim 1, wherein the plurality of elongate gas ports comprise at least one repeating unit of a first reactive gas port and a second reactive gas port.

14. The gas distribution plate of claim 13, wherein there are in the range of 2 to 24 repeating units.

15. An atomic layer deposition system, comprising:
a processing chamber;
a gas distribution plate comprising a body with a plurality of elongate gas ports extending along a width of the body with openings at a front face of the body, a left vacuum curtain channel extending along a length of the body adjacent a left side of the body and bounding at least some of the plurality of elongate gas ports, and a right vacuum curtain channel extending along the length of the body adjacent the right side of the body and bounding at least some of the plurality of elongate gas ports; and
a substrate carrier to move a substrate reciprocally with respect to the gas distribution plate in a back and forth motion along an axis perpendicular to an axis of the elongate gas injectors.

16. The atomic layer deposition system of claim 15, wherein the substrate carrier rotates the substrate.

17. The atomic layer deposition system of claim 16, wherein the rotation is continuous.

18. The atomic layer deposition system of claim 16, wherein the rotation is in discrete steps.

19. The atomic layer deposition system of claim 18, wherein each discrete step rotation occurs when the substrate carrier is not adjacent the gas distribution plate.

20. A gas distribution plate comprising
a body having a length, width, sides and front face;
a plurality of elongate gas ports spaced along the length of the body with openings extending along the width of the body at the front face, the plurality of elongate gas ports including one or more reactive gas ports, one or more purge gas ports and one or more vacuum ports;
a vacuum gas curtain channel extending along the length of the body adjacent a first side of the body and bounding at least some of the plurality of reactive gas ports; and
a vacuum gas curtain channel extending along the length of the body adjacent a second side of the body and bounding at least some of the plurality of reactive gas ports.
